(19) United States
(12) Patent Application Publication
(10) Pub. No.: US 2015/0376814 A1
(43) Pub. Date: Dec. 31, 2015

(54) PROCESS FOR PRODUCING MOULDED MICROMETIRC, SUBMICROMETRIC OR NANOMETRIC SIZED ELEMENTS MADE OF MONOCRYSTALLINE DIAMOND OR OF DIAMOND WITH A VERY LOW DENSITY OF GRAIN BOUNDARIES

(71) Applicant: COMMISSARIAT À L'ÉNERGIE ATOMIQUE ET AUX ÉNERGIES ALTERNATIVES, Paris (FR)

(72) Inventors: Hugues Girard, Viroflay (FR); Samuel Saada, Bourg La Reine (FR)

(73) Assignee: Commissariat à L'énergie atomique et aux énergies alternatives,, PARIS (FR)

(21) Appl. No.: 14/763,042

(22) PCT Filed: Jan. 27, 2014
(86) PCT No.: PCT/EP2014/051466

§ 371 Date: Jul. 23, 2015

(30) Foreign Application Priority Data
Jan. 29, 2013 (FR) 13 50746

(51) Int. Cl. C30B 25/18; C30B 29/04; C30B 25/10

(52) U.S. Cl. CPC C30B 25/186; C30B 25/105; C30B 29/04

(57) ABSTRACT

A process for producing moulded elements made of diamond of nanometric, submicrometric or micrometric sizes, the process comprising the following steps: a) forming beads of nanometric, submicrometric or micrometric sizes, each bead comprising a diamond nanoparticle embedded in an embedding material, by contacting diamond particles of nanometric sizes with an embedding material; b) introducing a bead into cavities of a sacrificial mould, the cavities forming a replica of the elements to be produced; c) removing the embedding material; d) forming diamond elements in the cavities containing a nanoparticle, by growing diamond from nanoparticles; e) releasing the diamond elements, by partially or totally removing the sacrificial mould.

### TECHNICAL FIELD

The present invention relates to a process for obtaining elements made of monocrystalline diamond or of diamond having a very low density of grain boundaries, the elements having a micrometric, submicrometric, or even nanometric size.

This process is especially applicable in all the fields in which it is useful to have a three-dimensional diamond structure, in particular for applications in optics, electrochemistry, electronics or even medicine (implants).

### STATE OF PRIOR ART

Diamond is a particularly interesting material due to its numerous exceptional properties, among which its biocompatibility, and its electrochemical, luminescence and heat conduction properties can be cited.

Developing this material in optics, in electronics, for making MEMS (“Micro ElectroMechanical Systems”) systems for example, or in any other technical field that can use effectively the interesting properties of the diamond requires making three-dimensional diamond elements, such as pillars, tips, disks, pyramids, etc. of micrometric, submicrometric, or even nanometric sizes.

Three-dimensional diamond elements are presently obtained by conforming thin diamond layers into a mould (and more precisely, into a cavity of a mould, if the mould comprises several cavities).

Synthetizing thin diamond layers is generally made by CVD (“Chemical Vapour Deposition”) growth. A thin diamond layer (in the range of a few tens nanometres to a few tens micrometres) is then deposited from a hydrogen and methane plasma on a substrate, which can be for example silicon, glass, a metallic layer, etc. Initiating the CVD growth on the substrate is made through using diamond nanoparticles, that have first been deposited on the substrate surface. These nanoparticles will then grow and form a diamond polycrystalline film, namely an assembly of coalesced diamond crystals connected to each other by grain boundaries.

Techniques of diamond nanoparticles deposition and of CVD growth are now very well controlled and can be made on so-called “planar” substrates, but also on substrates having 3D patterns. Thus, the surface of substrates having cavities (for example wells) can be covered with diamond and such substrates can act as moulds if the diamond layer fills the cavities. These moulds can be made of silicon or other materials, with cavities of micrometric, submicrometric or nanometric scale, and are dissolved at the end of growth in order to release diamond elements made in the mould patterns (cf. document [1]). This technique used to form 3D diamond elements is now well known and is particularly used for making diamond MEMS and nanopillars (cf. document [2]).

However, although this technique enables diamond nanometric elements to be made, the generated material is polycrystalline, due to the use of a great number of diamond nanoparticles deposited in the mould to initiate the CVD growth. Indeed, in order to reproduce the mould shape, its entire surface is covered before growing nanoparticles, the objective being to reach a maximum density (typically 10¹¹ particles/cm²). The resulting material therefore consists of an assembly of crystallites or diamond grains, with a proportion of grain boundaries directly related to the initial density of deposited nanoparticles. Furthermore, the size of these grains varies according to the density of nanoparticles deposited into the mould cavities and to the dimensions of these cavities. There can therefore be, at the end of the CVD growth, a grain size gradient within a same element.

Here lies the main limitation of this technique for making 3D diamond elements from sacrificial moulds. Indeed, in some cases, the polycrystalline aspect, the grain boundaries and the grain size gradient that can be found in this type of material are incompatible with the use of such elements in different fields such as optics, electronics or thermal dissipation. The presence of grain boundaries induces defects in the material and the non-continuity of the material due to its polycrystalline nature inhibits or strongly decreases some properties of the diamond, such as its thermal conduction, transport properties or optical properties (inhomogeneous refractive index and scattering phenomena, for example).

Three-dimensional diamond elements can also be obtained by etching thin diamond layers. This method, more complicated to implement than the above described method, has the advantage of enabling monocrystalline diamond elements to be made. To do so, growing a thick monocrystalline film (for example by a CVD process), then structuring thereof by selective etching are carried out. This approach is called “top-down” and requires the use of etching masks (deposited by optical or electronic lithography) and the use of specific etching techniques. With this method, elements of a very good crystalline quality can be obtained. By way of example, Babinec et al. have used this approach to make monocrystalline diamond nanopillars (0.2×2 μm) of an exceptional crystalline quality, in which luminescent centres have been integrated for generating and extracting single photons (cf. document [3]). After depositing an etching mask by electronic lithography, a thick sample of monocrystalline diamond is exposed to an RIE (“Reactive Ion Etching”) etching, releasing pillars of very small dimensions.

If the crystalline quality of the elements generated by this method meets the expectations, it however requires growing a thick diamond film, a large part of which will be finally etched, which represents a strong limitation in terms of cost and time.

Besides, this technology cannot be transferred at a large (industrial) scale, the initial monocrystalline diamond thin layers having presently very limited dimensions (5×5 mm, at the most).

Moreover, the etching and lithography techniques necessary for structuring diamond films differ from those generally used in the semiconductor industries (for example silicon), which accordingly limits their development.

In view of the abovementioned drawbacks, the inventors have set themselves the objective to implement a new production process which enables elements of monocrystalline diamond or of diamond having a very low density of grain boundaries, of micrometric, submicrometric or nanometric sizes and which can be industrially implemented, to be obtained.

### DISCLOSURE OF THE INVENTION

The process object of the invention is based on the principle according to which, by limiting the number of particles deposited into a same cavity of a mould, the polycrystallinity of the final material is accordingly reduced, the objective being, in the ideal case, to have a single diamond nanoparticle deposited at the bottom of a cavity in order to obtain, by CVD growth, a monocrystalline diamond element the final shape of which is the one of the cavity. The challenge for the inventors was therefore to be able to control the localized deposition of a limited number (or even equal to one, in the ideal case) of diamond nanoparticles in a cavity of micro, submicro or nanometric dimensions. But the use of a simple colloidal suspension of diamond nanoparticles does not allow such a result, mainly due to the suspension anisotropy (shape and size of the particles), the aggregation phenomena and the hardly controllable size of the nanoparticles. Even by strongly diluting the nanodiamond suspension, the probability of obtaining a single particle at the bottom of a cavity is very small.

The invention thus relates to a process for producing moulded elements made of diamond of nanometric, submicrometric or micrometric sizes, said process comprising the following steps:

a) forming beads of nanometric, submicrometric or micrometric sizes, each bead comprising a diamond nanoparticle embedded in an embedding material, by contacting diamond particles of nanometric sizes with an embedding material;

b) introducing a bead into cavities of a sacrificial mould, the cavities forming a replica of the elements to be produced;

c) removing the embedding material;

d) forming diamond elements in the cavities containing a nanoparticle (2), by growing diamond from nanoparticles;

e) releasing the diamond elements, by partially or totally removing the sacrificial mould.

Of course, the cavities of the mould have a shape adapted to obtain the elements to be produced. The cavities form a replica of the elements to be produced and reproduce the shape of the elements to be produced.

Preferably, in step b), it is attempted, if possible, to introduce a bead into each cavity of the sacrificial mould.

Preferably, the nanoparticles used in step a) are made of monocrystalline diamond.

After the step e), diamond elements are obtained, which are preferably monocrystalline or which, at the very least, have a very low density of grain boundaries. Within the scope of the present invention, an element of nanometric, submicrometric or micrometric sizes is considered to have a very low density of grain boundaries when it is formed, at the most, of four crystallites or crystals (knowing that each nanoparticle introduced into a cavity of the mould gives rise to a crystallite or crystal). The elements obtained by the process according to the invention have therefore an improved crystalline quality if compared with the elements obtained in the prior art by conforming a thin layer into a mould. Moreover, they are obtained in a much cheaper and quicker way than by etching a thin monocrystalline layer.

Before further detailing the disclosure of the invention, the following definitions will be specified.

Within the scope of the present invention, “nanoparticle” means a particle of nanometric sizes.

In the foregoing and following parts, the term “size” applied to particles or beads, refers to the largest dimension of these particles or these beads; the term “nanometric” means equal to or greater than 1 nanometre and equal to or lower than 100 nanometres; the term “submicrometric” means greater than 100 nanometres and lower than 1000 nanometres; the term “micrometric” means equal to or greater than 1 micrometre and lower than 1000 micrometres.

Besides, it must be reminded that the term “particle” refers to an element which ratio of the largest dimension to the smallest dimension is equal to or lower than 5.

In the foregoing and following parts, the term “bead” refers to a shell enclosing a diamond nanoparticle and which ratio of largest dimension to the smallest dimension is equal to or lower than 1.2. Beads can therefore have a spherical or nearly spherical shape.

The principle of the process object of the invention is based on the use of encapsulated diamond nanoparticles enabling them to be localized in the cavities of a mould and the use of the mould cavities to force the shape of elements of monocrystalline diamond or of elements having a low polycrystallinity obtained in these cavities by CVD growth from a single diamond nanoparticle or, at the most, from four diamond nanoparticles.

Encapsulating diamond nanoparticles in a suitable organic embedding material enables the nanoparticles to be isolated from each other. It also enables the shape of the elements (beads) suspended in a solution to be standardized, their size to be finely controlled to adapt it to the one of the mould cavities and improved colloidal properties to be imparted to them (steric and/or electrostatic repulsion). Thus, unlike conventional diamond nanoparticles the size in solution of which can be inhomogeneous (aggregation, particle size distribution) and the colloidal properties of which are poor, encapsulated particles have the colloidal properties of “perfect” spheres. The chemical synthesis of these beads enables their size distribution to be very finely controlled and gives nearly monodispersed suspensions. The diameter differences which are often observed in the diamond nanoparticle solutions are thus very significantly smoothed. Similarly, the shape anisotropy of the diamond particles (presence of facets, surface defects, etc.) is also smoothed by encapsulation, giving nearly perfect spheres. Both latter points (monodispersity and shape anisotropy) are essential to control the colloidal behaviour of particles. Finally, the chemical encapsulation enables the size of the beads to be adapted to the dimension of the mould cavities, in order to limit the number of particles deposited into a same cavity.

Then, through a suitable deposition of the encapsulated nanoparticle suspension (wet deposition, for example by dip coating or spin coating), a selective deposition of diamond nanoparticles into the mould cavities becomes possible as well as, thanks to the limitation of aggregation phenomena, to the native repulsion of beads from each other and by adjusting the dimension of the beads to the dimensions of the mould cavities, having only one bead per cavity and later, having CVD growing patterns of monocrystalline diamond or of a very low density of grain boundaries. Such depositions of nanometric spheres into the cavities of a mould have already been performed in literature and do not represent a significant technological limitation.

Regarding step a) of the process according to the invention, it can comprise the following successive operations:
dispersing the nanoparticles in a solvent (for example, water);
mixing the thus obtained suspension with one or more monomers, one or more cross-linking agents of the monomer and one or more initiators of a cross-linking reaction of the monomer, this mixing being made under stirring; and
polymerizing and cross-linking the monomer(s), to obtain the formation of a cross-linked polymer layer around the nanoparticles.

Regarding step b), it can comprise wet depositing beads into the mould cavities. Preferably, step b) is carried out by dip coating or spin coating. These techniques are well known to those skilled in the art and are described in literature (cf. document [4] for example).

It is reminded that the so-called dip coating technique consists in immersing the mould in the suspension containing the beads and in removing it from the suspension with a controlled speed. Within the scope of the present invention, if step b) is carried out by dip coating, the mould is preferably vertically extracted from the suspension at a constant controlled speed, typically lower than 10 μm/s.

For the spin coating technique, the surface of the mould is “swept” by the encapsulated particle suspension.

For these wet depositions, a capillarity effect and size effect are relied on to make the beads enter inside the mould cavities.

Regarding step c), it can be a chemical dissolution or a thermal destruction, destruction being preferably carried out with the plasma used during step d).

Regarding step d), diamond growth in the cavities from nanoparticles is carried out by plasma enhanced chemical vapour deposition. The plasma enhanced chemical vapour deposition is preferably carried out by using a gas stream comprising a carbon source, preferably one or more hydrocarbons, possibly mixed with hydrogen and/or one or more inert gases at a temperature ranging from 350° C. to 1000° C. and at a pressure ranging from ultra high vacuum to atmospheric pressure. It can be for example a CVD deposition using a hydrogen plasma and methane (mixture of H₂/CH₄ at 750° C.). The plasma used during the CVD growth can be created by using an energy source such as microwaves (MPCVD deposition), radiofrequencies (RFCVD deposition) or a hot wire (HFCVD deposition).

Step c) and step d) can be successively or simultaneously carried out.

Steps c) and d) are successively implemented when, for example, step c) of removing the embedding material from the beads is carried out by chemical dissolution, for example using a hydrofluoric acid solution.

Steps c) and d) are simultaneously implemented when, for example, step c) is carried out using the plasma used for the CVD growth of step d). The embedding material is then removed in situ during the CVD plasma. This destruction in situ is possible when the embedding material is a polymer, for example pNIPAM.

Regarding step e), the removal is preferably a chemical dissolution. For example, in the case of a silicon mould, it can be removed by using a mixture of hydrofluoric acid and nitric acid. Elements, once the mould is dissolved, can be retrieved by centrifugation or filtration.

Preferably, beads obtained after step a) have a diameter between 0.6 and 0.8 times the smallest dimension of the cavities, for example the diameter if the cavities are circular holes. Preferably, the mould cavities have a larger dimension and the ratio of the smallest dimension to the largest dimension is between 0.3 and 1. This ratio ensures a capillarity effect at the cavities, which facilitates the introduction of a single bead in each mould cavity.

The embedding material used in the process object of the invention can be any organic material able to embed a diamond nanoparticle into a spherical or nearly spherical-shaped shell. Preferably, the chosen material has a surface electrostatic repulsion, so that the beads, once made, have a native repulsion (steric and electrostatic repulsion) and repulse each other, thus preventing the beads from aggregating. It can be chosen from polymers the monomer of which is able to adsorb on a diamond nanoparticle (for example by covalent grafting, electrostatic interaction, hydrogen bond or Van der Waals bond). Monomers can for example be styrene (to make polystyrene beads), chitosan, methylmethacrylate (to make PMMA), N-isopropylacrylamide (to make pNIPAM), etc.

Once the monomer is adsorbed on the nanoparticle, the monomer can be polymerized. Preferably, the embedding material is pNIPAM.

The material of the sacrificial mould must be able to withstand exposure to the plasma used during the step d) of forming diamond elements; if the embedding material of the beads is removed by chemical dissolution in step c), the material of the mould must also be able to withstand the mixture used for this chemical dissolution. Finally, the chosen material must be able to be chemically dissolved. It is also desirable that the chosen material should be easily machinable, so that making the cavities is not too complicated. The material of the sacrificial mould can be chosen from a metal, a metallic alloy or an oxide. Advantageously, the mould is of silicon and is removed by chemical dissolution in a mixture of hydrofluoric acid and nitric acid.

One of the advantages of the process object of the invention is that it requires no “cumbersome” technological step in terms of means, but only a step of chemical synthesis to carry out the diamond nanoparticle encapsulation (formation of the beads). The advantage of this synthesis is that it can be carried out on a large volume of nanoparticles, the encapsulated particles being then perfectly stable over time.

The process object of the invention thus enables the production of diamond elements by a so-called “bottom-up” approach, by using already proven technologies: the structuration of the silicon mould can benefit from all the already known techniques for this material, already adapted to a large surface, and already industrially developed; nanodiamonds are available in an industrial quantity (especially through the polishing industry), their encapsulation only requires a few non-limiting chemical steps, and their deposition can be made by techniques already used in high technology industries (spin coating and/or dip coating); the removal of the embedding material from the beads can be made either directly in situ thanks to the plasma used during the CVD growth (for example in the case of a polymeric embedding), or beforehand by a chemical dissolution; the sacrificial mould can be removed by chemical dissolution.

In the end, the process according to the invention is much more economical in terms of cost and time with respect to the etching based approach described in the prior art. Moreover, thus obtained elements are not limited to the dimension of the initial material before its etching (with a thickness of generally a few millimetres for a thin monocrystalline diamond layer) and the process object of the invention requires no technologically cumbersome implementing steps (as is the case during the etching of a diamond layer).

The main patterns of the elements that can be made by the process object of the invention concern the production of tips, pillars or cones of monocrystalline diamond or of a very low density of grain boundaries, of nanometric to micrometric sizes, the replicas of these patterns being able to be easily made in a mould.

The absence or strong limitation of the number of grain boundaries in this type of patterns makes them very interesting for optics: there is presently a strong development of diamond devices for making single photon sources or photonic crystals of diamond. The improved quality of the material is also interesting for making electrochemical devices with a large developed surface (especially for making implants for the electric stimulation).

The present invention also relates to a process for producing a diamond structure comprising, on one of its faces, a plurality of elements of nanometric, submicrometric or micrometric sizes, said process comprising implementing the process for producing diamond elements of nanometric, submicrometric or micrometric sizes such as described above, a step being added between step d) and step e), and this step consisting in catalytically growing diamond by chemical vapour deposition from the elements obtained in step d), until a coalescence of elements is obtained, thus forming the structure.

Unlike the process for producing elements of nanometric, submicrometric or micrometric sizes, where the growth of the elements is stopped when the mould cavities are partially, and preferably totally, filled, for making the structure, the growth continues outside the cavities until the elements coalesce (adjacent element joining). The elements are then joined to each other, forming a structure which can be more easily manipulated than the elements themselves.

### BRIEF DESCRIPTION OF THE DRAWINGS

The invention will be better understood, and further details, advantages and characteristics thereof will appear upon reading the following description made by way of non-limiting example and with reference to the appended drawings in which:

FIG. 1 represents a schematic cross-section view of a bead as used in the process of the present invention;

FIG. 2 represents a perspective cross-section view of an exemplary mould used in the process of the present invention;

FIGS. 3a to 3d represent the steps of the process according to the invention.

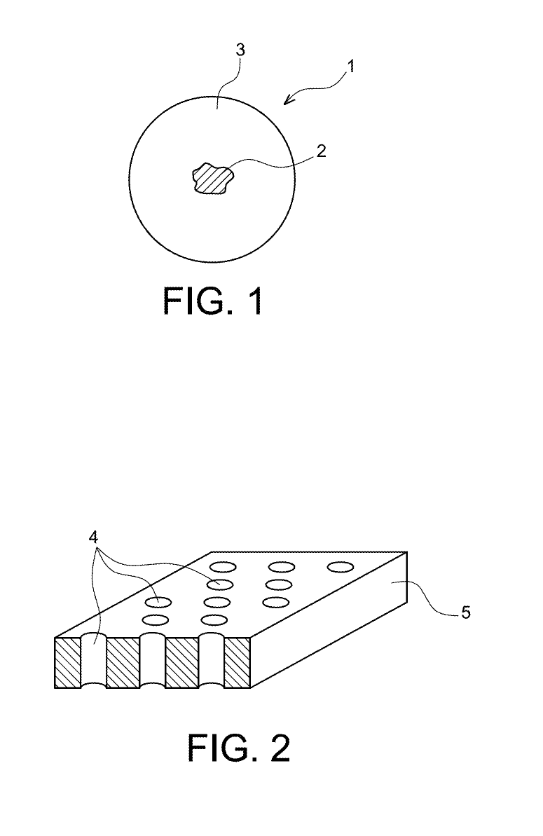

### DETAILED DISCLOSURE OF A PARTICULAR EMBODIMENT

In order to illustrate the process object of the invention, we are going to describe the formation of diamond pillars made from encapsulated nanodiamonds into a polymer referred to as pNIPAM.

To do so a pNIPAM colloidal solution is prepared by using an N-isopropylacrylamide solution (thereafter “NIPAM”) with a 97% concentration as a monomer, a N,N′-methylene-bis-acrylamide solution (thereafter “BIS”) with a more than 99.5% concentration as a cross-linking agent and a potassium persulfate solution (thereafter “KPS”) with a 99.99% concentration as the polymerization initiator. These solutions are those supplied by the Sigma-Aldrich company. The ultrapure water has a resistivity of 18.2 MΩ·cm (25° C.).

The followed operating mode is the one described by Pelton et al. in document [5].

In a beaker fitted with a magnetic stirring bar, 0.681 g of NIPAM at a concentration of 6.10⁻³ mol and 0.094 g of BIS at a concentration of 6.10⁻⁴ mol are introduced into 60 ml of previously degased ultrapure water and containing a concentration of 17 μg/ml of nanoparticles.

The nanoparticles used are nanodiamond (thereafter “ND”) sold by the Van Moppes company under reference Syndia® SYP 0-0.2 having an average diameter of 30 nanometres.

In order to remove the oxygen present in the solutions, the mixture of solutions and nanoparticles is strongly stirred for 20 minutes in the presence of a nitrogen stream. Then, the mixture is heated up to reaching a temperature of 70° C. and 0.6 ml of a 0.1M KPS solution (concentration of 6.10⁻⁵ mol) is added in order to initiate polymerization.

As soon as a mild opalescence appears, the stirring speed is lowered in order to avoid flocculation and the polymerization reaction is allowed to continue for 3h. Then, the microgel beads are retrieved and washed by performing several centrifugation-redispersion cycles using ultrapure water.

Beads 1 are obtained comprising a diamond nanoparticle 2 encapsulated into a shell of embedding material 3 (here pNIPAM) having a spherical or nearly spherical shape.

These beads 1 will be placed into cavities 4 of a mould 5 (FIG. 2).

It is to be noted that the size of the beads made is adjusted as a function of the size of the mould cavities. For this, we can rely on the size of the diamond nanoparticles and their concentration in the reaction mixture, as well as on the temperature of the beads once formed, as is shown in the table below.

The results presented in the table below have been obtained by carrying out several different syntheses using the above described operating mode and reagents, by changing the concentration (17, 50 and 500 μg/ml) and the average diameter of the diamond nanoparticles (30 nm and 100 nm). For the sample 4, nanodiamonds sold by the Van Moppes company under reference Syndia® SYP 0-0.1 have been used, with an average diameter of 100 nanometres.

The average diameter of the thus obtained beads has then been measured at 20° C. and 55° C. to highlight the heat sensitive properties of pNIPAM.

| | ND | ND | Bead diameter | Bead diameter |
|---|---|---|---|---|
| | diameter | concentration | at 20° C. | at 55° C. |
| | (nm) | (μg/ml) | (nm) | (nm) |
| Beads of | — | 0 | 525 | 315 |
| pNIPAM | | | | |
| only* | | | | |
| Sample 1 | 30 | 17 | 362 | 201 |
| Sample 2 | 30 | 50 | 259 | 154 |
| Sample 3 | 30 | 500 | 191 | 111 |
| Sample 4 | 100 | 50 | 467 | 257 |

*pNIPAM beads not containing any diamond nanoparticles.

It is noticed that the pNIPAM beads have a decreasing diameter when a diamond nanoparticle is introduced therein.

On the other hand, it is noticed that the diameter of the pNIPAM beads containing a diamond nanoparticle decreases when the temperature of the beads increases and when the nanoparticle concentration increases. Furthermore, when the average diameter of the nanoparticles introduced into the reaction mixture increased from 30 to 100 nm, with an identical concentration, the diameter of the bead thus obtained is also increased.

Thus, the choice of pNIPAM as an embedding material for diamond nanoparticles is wise within the scope of the present invention, since adding nanoparticles into the reaction medium (formed by the monomer, the cross-linking agent and the initiator) does not affect the general morphology of the polymer beads (spherical shape) and the size of beads can be reversibly modified by increasing the temperature.

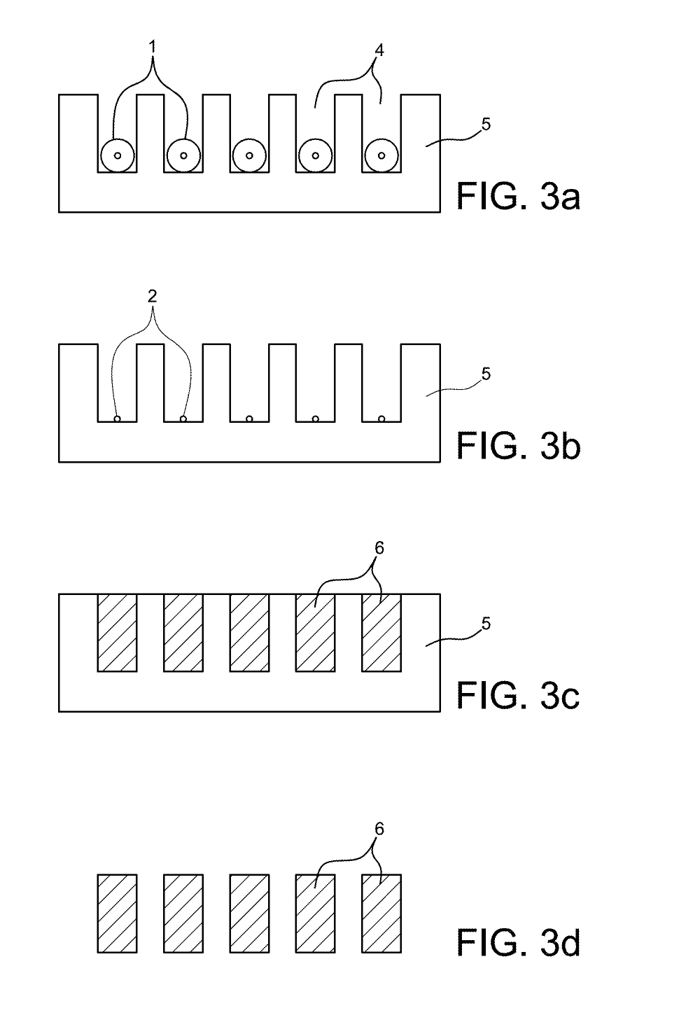

Once the diamond nanoparticles are encapsulated into pNIPAM, they can be placed into the cavities of a mould (FIG. 3a).

In our exemplary embodiment, the mould is made of silicon. It consists of a wafer comprising cavities, namely holes with a 600 nm diameter and a 1100 nm depth. Preferably, the holes have an opening (629 nm) wider than their bases (575 nm).

In order to carry out the deposition of the beads into the mould cavities, the simplest technique is based on the use of capillary forces and a convective effect, for example by spin coating or dip coating. This technique is well known to those skilled in the art and is described by Malaquin et al. (cf. document [4]).

Deposition of beads containing nanodiamonds into the mould cavities can thus be performed by vertical extraction from the mould of the colloidal suspension containing the beads at a constant controlled speed (typically a speed lower than 10 μm/s).

Thus, by adapting the diameter of the beads to the dimensions of the mould cavities—and consequently, to the dimensions of the elements to be made in these cavities—when a bead meets a cavity, it is deposited therein. Moreover, given the diameter of the beads, on the one hand, and the diameter and the depth of the holes on the other hand, the number of beads it is possible to introduce in each hole is limited, which leads to obtaining an element made of diamond which is monocrystalline or having a low crystallinity.

Then, once the beads have been deposited into the mould cavities, the mould thus filled can be transferred into a diamond CVD growing reactor. Under the effect of the hydrogen plasma and of methane (mixture of H₂/CH₄ at 750° C.), the polymeric shell of the beads is burnt, releasing the diamond particle at the bottom of the mould cavity (FIG. 3b). The chemical vapour deposition (CVD) technique enables the diamond particle to be grown. By finely controlling the growing parameters, elements 6 of an excellent crystalline quality material are obtained, the material being monocrystalline or very similar to a monocrystalline material, with very few grain boundaries (FIG. 3c).

Finally, once the growth of the diamond elements is over, the sacrificial mould 5 is removed in order to release the diamond elements 6 (FIG. 3d). The mould being of silicon, its removal is obtained by chemically dissolving it in a mixture of hydrofluoric acid and nitric acid. In this way, nanopillars of monocrystalline diamond can be obtained.

In the embodiment just described, a silicon mould has been used. It is however possible to use other materials for making the mould, with the provision that they can withstand exposure to a CVD plasma and they can be chemically dissolved.

Similarly, in the above embodiment, diamond nanoparticles have been embedded (or encapsulated) into a pNIPAM polymeric matrix. Other types of polymers can however be considered.

### MENTIONED REFERENCES

[1] Bongrain et al.
“Selective nucleation in silicon moulds for diamond MEMS fabrication”, Journal of Micromechanics and Microengineering, n^{o} 7, volume 19, pages 1-7 (2009).
[2] Girard et al.
“Electrostatic grafting of diamond nanoparticles towards 3D diamond nanostructures”, Diamond and Related Materials, volume 23, pages 83-87 (2012).
[3] Babinec et al.
“A diamond nanowire single-photon source”, Nature Nanotechnology, volume 5, pages 195-199 (2010).
[4] Malaquin et al.
“Controlled particle placement through convective and capillary assembly”, Langmuir, volume 23, n^{o} 23, pages 11513-11521 (2007).
[5] Pelton et al.
“Preparation of aqueous lattices with N-isopropylacrylamide”, Colloids and Surfaces, volume 20, pages 247-256 (1986).

What is claimed is:

1. A process for producing moulded elements made of diamond of nanometric, submicrometric or micrometric sizes, said process comprising the following steps:
a) forming beads of nanometric, submicrometric or micrometric sizes each bead comprising a diamond nanoparticle embedded in an embedding material, by contacting diamond particles of nanometric sizes with an embedding material;
b) introducing a bead into cavities of a sacrificial mould, the cavities forming a replica of the elements to be produced;
c) removing the embedding material;
d) forming diamond elements in the cavities containing a nanoparticle, by growing diamond from nanoparticles;
e) releasing the diamond elements, by partially or totally removing the sacrificial mould.

2. The process according to claim 1, wherein step a) comprises the following successive operations:
dispersing the nanoparticles in a solvent;
mixing the thus obtained suspension with one or more monomers, one or more cross-linking agents of the monomer and one or more initiators of a cross-linking reaction of the monomer, this mixing being made under stirring; and
polymerizing and cross-linking the monomer, to obtain the formation of a cross-linked polymer layer around the nanoparticles.

3. The process according to claim 1, wherein step b) comprises wet depositing beads in the mould cavities.

4. The process according to claim 3, wherein step b) is carried out by dip coating or spin coating.

5. The process according to claim 1, wherein step c) is a chemical dissolution or a thermal destruction.

6. The process according to claim 1, wherein growing diamond in step d) is made by plasma-enhanced chemical vapour deposition.

7. The process according to claim 1, wherein step c) and step d) are made successively or simultaneously.

8. The process according to claim 1, wherein removing in step e) is a chemical dissolution.

9. The process according to claim 1, wherein the nanoparticles used in step a) are made of mono crystalline diamond.

10. The process according to claim 1, wherein beads have a diameter between 0.6 and 0.8 times the smallest dimension of the cavities.

11. The process according to claim 10, wherein the cavities have a largest dimension and the ratio of the smallest dimension to the largest dimension is between 0.3 and 1.

12. The process according to claim 1, wherein the embedding material is chosen from polymers the monomer of which is able to adsorb on a diamond nanoparticle.

13. The process according to claim 12, wherein the embedding material is the pNIPAM polymer.

14. The process according to claim 1, wherein the material of the sacrificial mould is chosen from a metal, a metallic alloy or an oxide.

15. A process for producing a diamond structure comprising, on one of its faces, a plurality of elements of nanometric, submicrometric or micrometric sizes, said process comprising implementing the process for producing moulded elements of diamond of nanometric, submicrometric or micrometric sizes according to claim 1, a step being added between step d) and step e), this step consisting in catalytically growing diamond by chemical vapour deposition from the elements obtained in step d), until a coalescence of elements is obtained, thus forming the structure.
